(19) United States
(12) Patent Application Publication
(10) Pub. No.: US 2026/0211006 A1
(43) Pub. Date: Jul. 23, 2026

(54) MAGNETIC CURRENT SENSOR COMBINING TWO MEASUREMENT PATHS

(71) Applicant: SAFRAN ELECTRONICS & DEFENSE, PARIS (FR)

(72) Inventor: François GUILLOT, MOISSY-CRAMAYEL (FR)

(21) Appl. No.: 19/137,962

(22) PCT Filed: Dec. 11, 2023
(86) PCT No.: PCT/EP2023/085218

§ 371 Date: Jun. 11, 2025

(30) Foreign Application Priority Data
Dec. 12, 2022 (FR) FR2213190

(51) Int. Cl. G01R 15/18; G01R 19/25

(52) U.S. Cl. CPC G01R 15/183; G01R 19/25

(57) ABSTRACT

A flux gate current sensor comprising a magnetic core (13), a measurement winding (14), an excitation circuit (23) arranged to generate a digital excitation signal (Se), an acquisition circuit (17) arranged to acquire an analog measurement voltage (Ve) the from terminals of the measurement winding (14) and to produce a digital measurement signal (Sm), a demagnetization servocontrol circuit (32) arranged to use the digital measurement signal to produce a digital demagnetization (Sdm) signal for compensating magnetic flux produced by the current that is to be measured, a summer (36) arranged to sum the digital excitation signal and the digital demagnetization signal so as to obtain a digital injection signal (Si), and an injection circuit (37) arranged to produce an analog excitation current from the digital injection signal and to inject the analog excitation current into the measurement winding.

### PRIORT ART OF THE INVENTION

A magnetic flux gate current sensor makes use of the property of a magnetic material, forming a magnetic core, whereby it saturates from a certain magnetic excitation level: for an increasing magnetic field, the slope of the transfer function f between the magnetic field (commonly denoted B) and the magnetic induction (commonly denoted H) decreases greatly from a so-called saturation value of the magnetic core corresponding to the point of inflection of the curve B=f (H).

There is shown schematically in FIG. 1 a flux gate current sensor of the type known from document WO-A-2020/002184, intended to measure a current Im flowing in a conductor. The magnetic current sensor comprises a magnetic core 1, which extends around a conductor 2 in which the current Im that is to be measured flows, and a measurement winding 3 around the magnetic core 1. The sensor also comprises an excitation circuit 4 arranged for generating a digital excitation signal Se, an acquisition circuit 5 comprising an analog-to-digital converter (ADC) 6 and arranged for acquiring an analog measurement voltage from the terminals of the measurement winding 2 and for producing a digital measurement signal Sm. A demagnetization servocontrol circuit 7 is arranged to produce, from the digital measurement signal Sm and after low-pass filtering, a digital demagnetization signal Sdm that is an image signal of the current Im that is to be measured, also intended to compensate for a magnetic flux produced by the current Im that is to be measured. A summer 8 sums the digital excitation signal Se and the digital demagnetization signal Sdm in order to obtain a digital injection signal Si. An injection circuit 9, comprising a DAC 10, is arranged to produce an analog excitation current Ie from the digital injection signal Si and to inject the analog excitation current Ie into the measurement winding 3.

Flux gate current sensors are preferred in certain applications. This applies in particular to measuring a current flowing in a cut-off member of the solid-state power controller (SSPC) type for user equipment, or else to measuring a current flowing in an energy converter member of the power electronic module (PEM) type connected to a phase of a motor.

However, the implementation of such a current sensor tends to limit the bandwidth of the measured signal. However, there is a growing need to measure currents over a wider bandwidth. In addition, it is also desirable to better measure the DC components, as well as the amplitude and phase of the AC components.

### OBJECT OF THE INVENTION

An object of the invention is to meet this need at least in part.

### SUMMARY OF THE INVENTION

To this end, according to the invention, there is provided a magnetic current sensor comprising a magnetic core that extends around a conductor in which there flows a current that is to be measured, a measurement winding, an excitation circuit arranged to generate a digital excitation signal, an acquisition circuit comprising an analog-to-digital converter and arranged to acquire an analog measurement voltage from the terminals of the measurement winding and to produce a digital measurement signal, a demagnetization servocontrol circuit arranged to use the digital measurement signal to produce a digital demagnetization signal for compensating magnetic flux produced by the current that is to be measured, a summer arranged to sum the digital excitation signal and the digital demagnetization signal so as to obtain a digital injection signal, and an injection circuit comprising a digital-to-analog converter and arranged to produce an analog excitation current from the digital injection signal and to inject the analog excitation current into the measurement winding. The sensor comprises a processing circuit having a first path for processing the demagnetization signal and a second path for processing the digital measurement signal which are connected to an summer in order to supply an image signal of the current, the second processing path being arranged in order to cancel out in the digital measurement signal at least a portion corresponding to a fundamental component of the digital excitation signal and comprising a high-pass filter strictly complementary to the first low-pass filter.

In the sensor of the invention, two signals that have undergone different processing are added in order to obtain the image signal of the current that is to be measured. The first processed signal is the demagnetization signal which is provided by the flux gate circuit and incorporates a DC component but has a relatively low bandwidth due to the low-pass filtering of the demagnetization servocontrol circuit. The digital measurement signal, which has not passed through the demagnetization servocontrol circuit, has a relatively large bandwidth but includes at least a portion corresponding to a fundamental component of the digital excitation signal. The second processing path makes it possible to cancel out this component. By adding the signals leaving the two processing paths, an image signal of the current is thus obtained, that benefits from the increased bandwidth of the digital measurement signal in the high frequencies while maintaining the richness of the demagnetization signal in the low frequencies. It is also possible to obtain two summed signals at the end of the filtering operations having an amplitude response as a function of the strictly constant frequency.

According to characteristics that are optional:
the second processing path comprises a first loop for extracting, from the digital measurement signal, a portion corresponding to an in-phase amplitude of the fundamental component of the digital excitation signal and a second loop for extracting, from the digital measurement signal, a portion corresponding to a quadrature amplitude of the fundamental component of the digital excitation signal and, preferably, the second path comprises at least one gain balancing component between the loops;
the digital excitation signal is obtained from a digital reference signal of frequency f0 and from a digital reference signal of frequency 3.f0; the excitation circuit preferably comprising an excitation servocontrol circuit which is arranged to servocontrol the digital excitation signal so as to cancel out a component of frequency 3.f0 of the analog measurement voltage; the excitation servocontrol circuit preferably comprising a first multiplier arranged to multiply the digital measurement signal by a digital demodulation signal of frequency 3.f0; the excitation servocontrol circuit preferably further comprising an integrator, a first amplifier connected to an output of the integrator and arranged to produce a digital error signal, and a second multiplier that multiplies a raw digital excitation signal by the digital error signal to obtain the digital excitation signal; the demagnetization servocontrol circuit comprising a third multiplier arranged to multiply the digital measurement signal by a digital demodulation signal of frequency 2.f0; the demagnetization servocontrol circuit preferably further comprising a second amplifier connected to an output of the first low-pass filter and arranged to produce the digital demagnetization signal;
the sensor includes at least one member for balancing the gain between the two processing paths.

The invention shall be better understood in the light of the following description of a specific and non-limiting embodiment of the invention.

### BRIEF DESCRIPTION OF THE DRAWINGS

Reference will be made to the accompanying drawings, in which:

FIG. 1 schematically shows a flux gate current sensor according to the prior art;

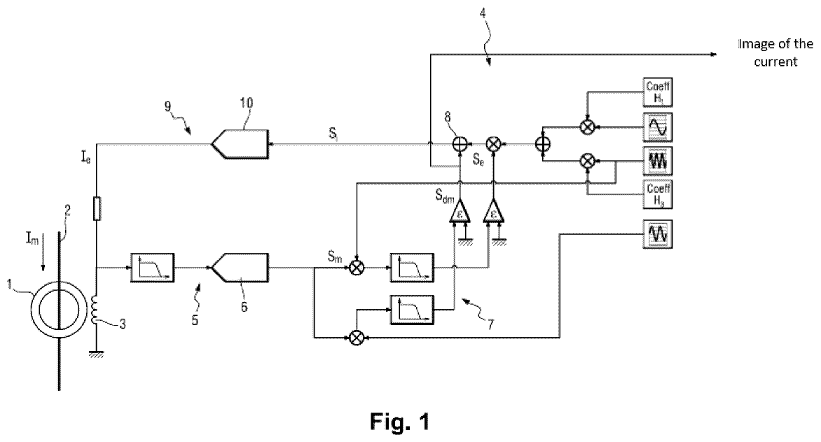

FIG. 2 schematically shows a flux gate current sensor according to the invention;

### DETAILED DESCRIPTION OF THE INVENTION

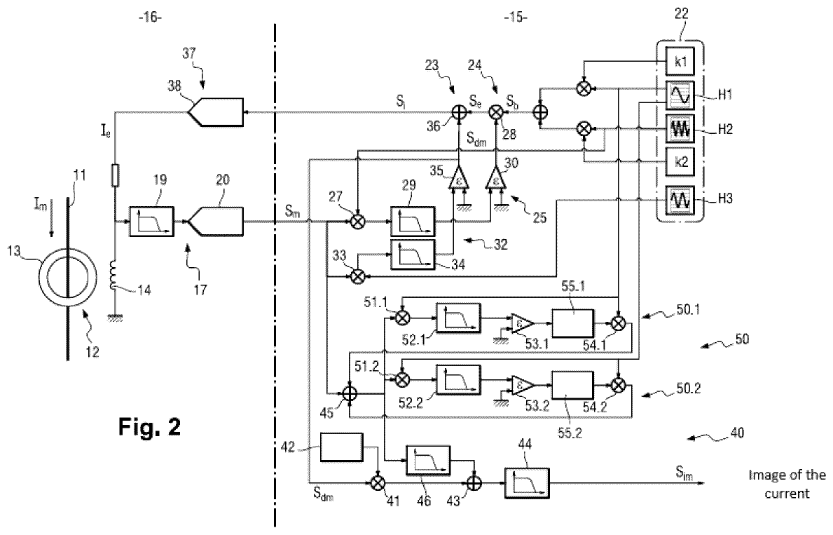

With reference to FIG. 2, a flux gate current sensor 10 according to the invention is used in this case to measure a current Im that is to be measured and that flows in a conductor 11.

The flux gate current sensor includes a transformer 12 comprising a magnetic core 13, a primary winding, and a secondary winding. The primary winding is the conductor 11. The magnetic core 13 extends around the conductor 11. The secondary winding is a measurement winding 14 wound around the magnetic core 13.

The flux gate current sensor includes a plurality of electronic components forming a digital portion 15 and an analog portion 16.

The digital portion 15 includes a digital processor component, which is specifically a field programmable gate array (FPGA), but which could be some other component: a microcontroller, a processor, an application-specific integrated circuit (ASIC), etc.

The flux gate current sensor further comprises an acquisition circuit 17. The acquisition circuit 17 forms part of the analog portion 16.

The acquisition circuit 17 is connected to the measurement winding 14.

The acquisition circuit 17 comprises a low-pass filter 19 and an analog-to-digital converter (ADC) 20 connected to an output of the low-pass filter 19. The low-pass filter 19 performs a spectrum anti-aliasing function and here has a cut-off frequency of about 10 MHz, but other values can be used.

In this case, the analog-to-digital converter 20 is a 12-bit converter having its operation clocked at a sampling frequency Fech. In this case, Fech=100 MHz. The ADC 20 could naturally present characteristics that are different.

The acquisition circuit 17 acquires an analog measurement voltage Ve from the terminals of the measurement winding 14. The measurement voltage Ve is applied as input to the low-pass filter 19.

The resulting voltage is applied as input to the ADC 20, which produces a digital measurement signal Sm.

The flux gate current sensor 10 includes a high frequency generator 22 known per se. The high frequency generator 22 is incorporated in the FPGA (where term “incorporated” could be replaced by any of the following terms: programmed, implemented, provided, etc.)

The high frequency generator 22 produces a digital reference signal of frequency f0 (or signal H1), a digital reference signal of frequency 2.f0 (or signal H2), and a digital reference signal of frequency 3.f0 (or signal H3).

In this case, the digital reference signal of frequency f0 is of the form:

$$S 1 r = sin ( ω0 t ) .$$

In this case, the digital reference signal of frequency f0 is of the form:

$$S 2 r = cos ( 2 \cdot ω0 t ) .$$

In this case, the digital reference signal of frequency f0 is of the form:

$$S 3 r = sin ( 3 \cdot ω0 t ) .$$

The flux gate current sensor further comprises an excitation circuit 23. The excitation circuit 23 is implemented in the FPGA.

The excitation circuit 23 is connected to the high frequency generator 22 and comprises a raw excitation circuit 24 and an excitation servocontrol circuit 25.

The raw excitation circuit 24 receives the digital reference signal of frequency f0 and the digital reference signal of frequency 3.f0, and from these signals it produces a partial digital excitation signal of frequency f0 and a partial digital excitation signal of frequency 3.f0.

In this case, the partial digital excitation signal of frequency f0 is of the form:

$$S 1 p = k 1 \cdot sin ( ω0 t ) .$$

In this case, the partial digital excitation signal of frequency f0 is of the form:

$$Sb = S 1 p + S 3 p = k 1 \cdot sin ( ω0 t ) + k 2 \cdot sin ( 3 ω0 t ) .$$

The raw excitation circuit 24 adds together the partial digital excitation signal of frequency f0 and the partial digital excitation signal of frequency 3.f0 in order to generate a raw digital excitation signa Sb. The raw digital excitation signal is of the form:

$$S 3 p = k 2 \cdot sin ( 3 \cdot ω0 t ) .$$

The excitation servocontrol circuit 25 is connected to the high frequency generator 22 to receive the digital reference signal of frequency 3.f0, and is arranged to produce from this digital reference signal of reference 3.f0, a digital demodulation signal of frequency 3.f0.

In this example, the digital demodulation signal of frequency 3.f0 is of the form:

$$S 3 d = k 3 \cdot sin ( 3 \cdot ω0 t ) .$$

The excitation servocontrol circuit 25 includes a first multiplier 27, a second multiplier 28, an integrator 29, and a first amplifier 30. The first amplifier 30 is connected to an output of the integrator 29.

The first multiplier 27 multiplies the digital measurement signal Sm by the digital demodulation signal of frequency 3.f0. The resulting signal is applied as input to the integrator 29. It should be observed that the first multiplier 27 and the integrator 29 act as a first synchronous demodulator.

The first amplifier 30 thus produces a digital error signal. The second multiplier 28 multiplies the raw digital excitation signal Sb by the digital error signal to obtain a digital excitation signal Se. The digital excitation signal is of the form:

Se=k0.(k1. sin(ω0t)+k2. sin(3ω0t)).

The flux gate current sensor further comprises a demagnetization servocontrol circuit 32. The demagnetization servocontrol circuit 32 is incorporated in the FPGA.

The demagnetization servocontrol circuit 32 is connected to the high frequency generator 22 to receive the digital reference signal of frequency 2.f0, and is arranged to produce from this digital reference signal of reference 2.f0, a digital demodulation signal of frequency 2.f0.

In this example, the digital demodulation signal of frequency 2.f0 is of the form:

$$S 2 d = k 4 \cdot cos ( 2 \cdot ω0 t ) .$$

The demagnetization servocontrol circuit 32 includes a third multiplier 33, a low-pass filter 34, and a second amplifier 35. The second amplifier 35 is connected to an output of the low-pass filter 34.

The third multiplier 33 multiplies the digital measurement signal Sm by the digital demodulation signal of frequency 2.f0. The resulting signal is applied as input to the low-pass filter 34. The second amplifier 35 thus produces a signal that is a digital image of the current Im that is to be measured, which signal is also a digital demagnetization signal Sdm. The digital image signal, or digital demagnetization signal Sdm, is of the form:

$$Sdm = k \cdot Im .$$

It should be observed that the third multiplier 33 and the low-pass filter 34 act as a second synchronous demodulator. The flux gate current sensor further comprises a summer 36. The summer 36 is implemented in the FPGA.

The summer 36 sums the digital excitation signal Se and the digital demagnetization signal Sdm in order to obtain a digital injection signal Si.

### Specifically:

$$Si = k 0 \cdot ( k 1 \cdot sin ( ω0 t ) + k 2 \cdot sin ( 3 ω0 t ) ) + k Im .$$

The flux gate current sensor further includes an injection circuit 37. The injection circuit 37 forms part of the analog portion 16. The injection circuit 37 is connected to the summer 36 and to the measurement winding 14.

The injection circuit 37 comprises a digital-to-analog converter (DAC) 38.

In this example, the DAC 38 is a 12-bit converter, and its operation is clocked at the frequency Fech (Fech=100 MHz). The DAC 38 could naturally present characteristics that are different.

The DAC 38 acquires the digital injection signal Si, produces an analog excitation current Ie from the digital injection signal Si, and injects the excitation current Ie into the measurement winding 14.

The flux gate sensor further comprises a processing circuit 40 for processing the digital image signal or digital demagnetization signal Sdm and the digital measurement signal Sm.

The processing circuit 40 comprises a first processing path having as input a multiplier 41 having a first input receiving the digital demagnetization signal Sdm, a second input receiving data coming from a memory 42 and an output connected to a first input of a summer 43 having an output connected to an input of a low-pass filter 44 having a cut-off frequency equal to one tenth of the sampling frequency. As will be seen later, the low-pass filter 44 outputs a digital image signal of the measured current without the fundamental and harmonics of the excitation signal. The memory 42 is a non-volatile memory that a contains coefficient to be applied to the demagnetization signal Sdm by the multiplier 41 to balance the amplitude of the demagnetization signal Sdm at input to the summer 43 with the amplitude of the digital measurement signal Sm. Specifically, the two measurement paths do not necessarily have exactly the same amplitude gains. However, in order to guarantee the flatness of t the frequency response throughout the entire measurement frequency band, it is necessary for the two measurement paths to have the same gain. To achieve this objective, in the “factory” setting phase, an AC current of constant amplitude is injected (into the wire in which the current to be measured flows) and swept from a frequency that is much lower than the cut-off frequency of the transition filter to a frequency that is much higher than this transition frequency. The value of the gain coefficient to be applied to obtain this frequency response flatness is adjusted. Once obtained, this coefficient is recorded in the memory (or could also be called a non-volatile memory register). In a variant, provision may be made for the memory 42 to contain a table containing coefficients at different temperatures and for the sensor to comprise a temperature probe in order to be able to select from the table the coefficient to be applied for the measured temperature.

The processing circuit 40 also comprises a second processing path comprising a servocontrol circuit 50 for servocontrolling to zero the portion of the measurement signal Sm corresponding to the fundamental component of the excitation signal. The servocontrol circuit 50 comprises two servocontrol loops 50.1, 50.2 each comprising: a first multiplier 51.1, 51.2; a low-pass filter 52.1, 52.2 having an input connected to an output of the multiplier 51.1, 51.2; an amplifier 53.1, 53.2 having an input connected to an output of the low-pass filter 52.1, 52.2; a second multiplier 54.1, 54.2 having a first input connected to the output of the amplifier 53.1, 53.2.

The multiplier 51.1 has a first input connected to an output of a summer 45 arranged as input to the second processing path 40 and a second input connected to the frequency generator 22 for receiving an in-phase amplitude signal of the digital reference signal of frequency f0. The multiplier 54.1 has a second input connected to the frequency generator 22 for receiving the in-phase amplitude signal of the digital reference signal of frequency f0 and an output connected to a first input of the summer 45. The multiplier 51.2 has a first input connected to the output of the summer 45 and a second input connected to the frequency generator 22 for receiving a quadrature amplitude signal of the digital reference signal of frequency f0. The multiplier 54.2 has a second input connected to the frequency generator 22 for receiving the quadrature amplitude signal of the digital reference signal of frequency f0 and an output connected to a second input of the summer 45.

It should be noted that the multiplier 51.1 and the low-pass filter 52.1 form a synchronous demodulator of the in-phase amplitude signal of the digital reference signal of frequency f0 and that the multiplier 51.2 and the low-pass filter 52.2 form a synchronous demodulator of the quadrature amplitude signal of the digital reference signal of frequency f0.

Each amplifier 53.1, 53.2 is associated with a memory 55.1, 55.2 containing an adjustable gain coefficient to equalize the gains of the two processing paths for values close to the cut-off frequency of the filters.

The memories 55.1 and 55.2 contain the values of the amplitude of the component H1 (in I and in Q) of the excitation signal of the magnetic core 13. These values will be used to inject into the signal reported at the output of the A/D converter a signal having these values in phase opposition so as to cancel out the excitation component H1 in the reported signal. Specifically, the excitation of the magnetic core 13 by the component H1 is found at the direct output of the analog/digital converter and it must therefore be removed so as not to distort the measurement. In doing so, it is necessary not to remove a component that would come from the outside (i.e. From the current to be measured) and that would be close to the excitation component H1, which would be done by the two control loops 50.1 and 50.2 at 0 of H1 (these loops are not capable of distinguishing an internal signal resulting from the excitation of an external signal coming from the current to be measured). The stored values are obtained during an initialization phase, without an external current (the current Im is zero), by recording the amplitude values I and Q of the excitation component H1 in the memories 55.1 and 55.2 with coefficients determined in order to dose the values I and Q of cancellation of H1 comprising exactly the values received at the output of ADC, components resulting from the excitation.

The summer 45 of the second processing path has a third input receiving the digital measurement signal Sm. The output of the summer 45 is also connected to an input of a high-pass filter 46 having an output (forming the output of the second processing path) connected to a second input of the summer 43. The low-pass filter 46 is strictly complementary to the high-pass filter 34.

There follows a description of the operation of the flux gate current sensor.

The excitation circuit 23 generates a digital excitation signal Se, which is transformed into an excitation current Ie and injected into the measurement winding 14.

The measurement voltage Ve is acquired and then digitized in order to produce a digital measurement signal Sm.

A signal that is a digital image of the current Im that is to be measured is obtained at the output of the second amplifier 35. This digital image signal is used to estimate the current Im that is to be measured after passing through the processing circuit 40.

The digital image signal is also a digital demagnetization signal Sdm that serves to compensate the magnetic flux produced by the current Im that is to be measured.

By means of the summer 36 and the parallel connection, it is easy to add together the digital demagnetization signal Sdm and the digital excitation signal Se. The excitation current thus serves both to excite the magnetic core 13 and also to demagnetize the magnetic core 13. The demagnetization current is thus incorporated in the excitation current Ie.

Saturation of the magnetic core 13 gives rise to asymmetry in the measurement voltage Ve, said measurement voltage Ve being constituted by the sum of a sin (ω0t) component of frequency f0, corresponding to the fundamental or H1, and of a cos (2ω0t) component of frequency 2.f0, corresponding to the second order harmonic component or H2.

It should be observed that the amplitudes of the partial digital excitation signal of frequency f0 and of the partial digital excitation signal of frequency 3.f0 are set so as to obtain an excitation current Ie in which the component of frequency 3.f0 (or third order harmonic component or H3) is in phase with the component of frequency f0.

The third harmonic component of the measurement voltage Ve, as obtained after synchronous demodulation using the first synchronous demodulator, is positive. In the event of the magnetic core 13 saturating, the third harmonic component is attenuated more strongly than the fundamental, and, after synchronous demodulation, the third harmonic component becomes negative, since the third harmonic goes into phase opposition with the fundamental.

Thus, when the excitation current Ie is such that the magnetic core 13 approaches saturation, the ratio of the amplitudes of the first harmonic component (i.e. the fundamental) and of the third harmonic component of the measurement voltage Ve varies until the third harmonic component becomes zero, and then until the phase of the third harmonic component is inverted. The operating point corresponding to the third harmonic component of the measurement voltage Ve becoming zero is thus the optimum operating point for the flux gate current sensor.

A digital error signal is obtained at the output from the first amplifier 30.

The digital error signal serves to servocontrol the excitation current Ie. The servocontrol consists in controlling the excitation current Ie so as to zero the third harmonic component of the measurement voltage Ve.

The flux gate current sensor thus operates continuously on the optimum operating point. This serves to obtain maximum gain of the asymmetries that are introduced by the current Im that is to be measured and that are detectable in the measurement voltage Ve. It should be observed that this servocontrol by synchronously demodulating the third harmonic component is relatively insensitive to external electromagnetic disturbances, since all of the signals of frequency other than the frequency 3.f0 generate intermodulation products having components that are filtered by the low-pass filter 34 connected to the output of the third multiplier 33. It may also be observed that this servocontrol does not need to be very fast, since the variations that come from external parameters (temperature, ageing) are relatively slow.

The demagnetization servocontrol circuit 32 makes it possible to cancel out the second harmonic component (the even harmonic components in general) by a zero servocontrol.

Furthermore, it is understood that the second processing path (or low-frequency measurement path which also conveys the DC component of the measurement signal) recovers a measurement signal in a relatively direct manner by implementing an intensity transformer principle and is associated with the first processing path (or high-frequency measurement path) by summing these two paths which are adjusted by strictly complementary filters, one high-pass (the filter 46 of the second processing path) and the other low-pass (the filter 34 of the first processing path). In the second processing path, the gain coefficient adjustable by programming which is stored in the memory 42 makes it possible to equalize the gains of the two processing paths of the digital measurement signal Sm for the values close to the cut-off frequency of the filters (memories 55.1 and 55.2). The digital processing makes it possible to ensure the strict linearity of the amplitude response so that the amplitude response is strictly constant, even at the junction of the cut-off frequencies of the high-pass and low-pass filters. The high-pass filter 46 and the low-pass filter 34 have cut-n off frequencies, attenuation slopes as a function of frequency and responses, which are identical. The two signals summed at the end of the filtering operations have an amplitude response as a function f the strictly constant frequency.

In addition, the processing circuit 40 ensures the cancellation of the fundamental component of the excitation by amplitude and complementary phase addition of the reference signal having the frequency f0 from the internal generator 22. The precise dosage is ensured by the double loop 50.1, 50.2 slaved to the cancellation of the fundamental component. Indeed, the fundamental component resulting from the excitation of the flux gate appears as a “useful” signal in the bandwidth of the first processing path. To cancel it out, it is necessary to measure it, record its amplitude and reinject it exactly in opposition to that received. However, the exact phase of this fundamental component in the first treatment path is not controlled because of the previous filtering. The second processing path makes it possible to simultaneously measure the amplitude I (in phase) and the amplitude Q (in quadrature) of the fundamental component of the digital measurement signal Sm, then to high-pass filter these two components before from subtracting, the digital demagnetization signal leaving the multiplier 41, these two components filtered (by the filter 46) in order to obtain a resulting signal which, after filtering by the filter 44, will constitute the image signal Sim. It is recalled that the amplitude values of the signal H1 received by the A/D converter 20 and to be removed from the measured signal are quantized during the initialization phase of the system and that these values are recorded in the memories 55.1 and 55.2 configured at the factory. The aim is not to “erase” from the signal to be measured any DC component that is identical to that of the excitation signal and that appears from outside the system during the operating phases.

The other “parasitic” spectral components (second and third harmonics), capable of being picked up by the intensity transformer, are in principle cancelled out in the excitation signal by the excitation servocontrol circuit and the demagnetization servocontrol circuit.

### Specifically:

the demagnetization servocontrol circuit 32 injects a direct current into the excitation signal to compensate for the magnetic imbalance produced by the current to be measured. The absence of magnetic imbalance results in an absence of even harmonics.
The excitation servocontrol circuit 25 cancels out the third harmonic component by zero servocontrol so as to be at the point of inflection of the curve B=f (H) of the magnetic core 13.

It is noted that the measurement winding 14 is used simultaneously to excite the magnetic core 13, to control the excitation, to measure the current Im that is to be measured, and to compensate the magnetic flux produced in the magnetic core 13 by the current Im that is to be measured (demagnetization).

Mutualization of the functions in a single measurement winding 14 serves to simplify the flux gate current sensor 10, to reduce its cost and weight, and to facilitate its manufacture.

It should also be observed that the system for processing measurement is mainly digital: a single FPGA serves to perform a major portion of this processing system. Digitizing the processing system increases its reliability and its robustness (in particular in terms of temperature), reduces its cost, facilitates its manufacture, and improves its industrial reproducibility.

The improvement in regulating the operating point that results from the demodulation performed by the first synchronous demodulator also serves to obtain better noise immunity.

Furthermore, the use of synchronous demodulators makes it possible to operate at high frequency, thereby permitting a wide bandwidth for the current Im that is to be measured, while conserving very good immunity to external electromagnetic disturbances.

Since measurement is always performed at the optimum operating point corresponding to the saturation bend 9, the sensitivity of the flux gate current sensor is constant in the temperature range. The accuracy of the flux gate current sensor 10 is thus good over a large temperature range.

As mentioned above, the flux gate current sensor 10 measures a current Im that is to be measured and that flows in a conductor 11.

The bandwidth is ultimately limited by the sampling frequency and the non-aliasing criterion (Shannon). For example, with a sampling done at 100 Ms/s and a simple anti-aliasing filter, it is possible to expect a bandwidth of up to 10 MHz.

It should be noted that to ensure its proper operation, the transformer 12 is loaded by the source resistance of the excitation (it is therefore not “empty”).

Naturally, the invention is not limited to the embodiment described, but covers any variation falling within the scope of the invention as defined by the claims.

The structure of the sensor may be different.

It is stated that the flux gate current sensor comprises a digital portion and an analog portion, and that the ADC and the DAC form parts of the analog portion. Naturally, it could be considered that these components are digital components, and even that they are incorporated directly in the FPGA (or in a microcontroller or in some other component), in which case they would form parts of the digital portion.

When the current that is to be measured is large, a major difficulty arises. The demagnetization current, which serves to compensate the magnetic flux produced in the magnetic core 13 by the current Im that is to be measured, must also be very large. The magnitude of the demagnetization current needs to be equal to the magnitude of the current that is to be measured divided by the transformation ratio of the transformer 12, which is associated with the characteristics of the primary winding and of the secondary winding. However, the number of turns of the measurement winding 14 is limited by its size and by the resulting inductance. The greater the inductance, the more the rate of change of the demagnetization current (coming from the digital demagnetization signal Sdm) is limited, and thus the more the bandwidth of the flux gate current sensor is limited. Thus, increasing the number of turns of the secondary winding is not an effective solution. Increasing the demagnetization current is not an effective solution either. Specifically, that would involve generating a demagnetization voltage that is very large associated with a demagnetization current that is large, which is difficult to achieve using standard components. In order to solve this difficulty, use can be made of a current divider bridge so as to reduce the magnitude of the current that is to be measured.

Loops 50.1 and 50.2 may be of a different structure.

It is possible to use gain balancing components between the loops 50.1, 50.2 other than the coefficients of the memories 55.1, 55.2.

It is possible to use another gain balancing member between the two processing paths than the coefficients of the memory 42 associated with the multiplier 41.

The excitation servocontrol circuit 25 and the demagnetization servocontrol circuit 32 may be of a structure different from that described. The same applies to both treatment pathways.

1. Magnetic current sensor, comprising a magnetic core (13) that extends around a conductor (11) in which a current (Im) to be measured flows, a measurement winding (14), an excitation circuit (23) arranged to generate a digital excitation signal (Se), an acquisition circuit (17) comprising an analog-to-digital converter (20) and arranged to acquire an analog measurement voltage (Ve) across the terminals of the measurement winding (14) and to produce a digital measurement signal (Sm), a demagnetization servocontrol circuit (32) arranged to produce, from the digital measurement signal and after a first low-pass filter, a digital demagnetization signal (Sdm) for compensating magnetic flux produced by the current that is to be measured, a summer (36) arranged to sum the digital excitation signal and the digital demagnetization signal so as to obtain a digital injection signal (Si), and an injection circuit (37) comprising a digital-to-analog converter (38) and arranged to produce an analog excitation current from the digital injection signal and to inject the analog excitation current into the measurement winding, characterized in that the sensor comprises a processing circuit (40) having a first path for processing the demagnetization signal and a second path for processing the digital measurement signal that are connected to a summer for supplying an image signal of the current, the second processing path being arranged to cancel out from the digital measurement signal at least a portion corresponding to a fundamental component of the digital excitation signal and comprising a high-pass filter that is strictly complementary to the first low-pass filter.

2. The sensor according to claim 1, wherein the second processing path comprises a first loop (50.1) for extracting, from the digital measurement signal, a portion corresponding to an in-phase amplitude of the fundamental component of the digital excitation signal and a second loop (50.2) for extracting, from the digital measurement signal, a portion corresponding to a quadrature amplitude of the fundamental component of the digital excitation signal.

3. The sensor according to claim 2, wherein the second path comprises at least one gain balancing component between the loops.

4. The sensor according to claim 1, wherein the digital excitation signal is obtained from a digital reference signal of frequency f0 and from a digital reference signal of frequency 3.f0.

5. The sensor according to claim 4, wherein the excitation circuit includes an excitation servocontrol circuit (25) that is arranged to servocontrol the digital excitation signal in such a manner as to zero a component of frequency 3.f0 of the analog measurement voltage.

6. The sensor according to claim 3, wherein the excitation servocontrol circuit includes a first multiplier (27) arranged to multiply the digital measurement signal by a digital demodulation signal of frequency 3.f0.

7. The sensor according to claim 6, wherein the excitation servocontrol circuit further includes an integrator (29), a first amplifier (30) connected to an output of the integrator and arranged to produce a digital error signal, and a second multiplier (28) that multiplies a raw digital excitation signal (Seb) by the digital error signal in order to obtain the digital excitation signal.

8. The sensor according to claim 7, wherein the demagnetization servocontrol circuit includes a third multiplier (33) arranged to multiply the digital measurement signal by a digital demodulation signal of frequency 2.f0.

9. The sensor according to claim 8, wherein the demagnetization servocontrol circuit further includes a second amplifier (35) connected to an output of the first low-pass filter (34) and arranged to produce the digital demagnetization signal.

10. The sensor according to claim 1, comprising at least one gain balancing member between the two processing paths
